(19) United States
(12) Patent Application Publication
(10) Pub. No.: US 2025/0275423 A1
(43) Pub. Date: Aug. 28, 2025

(54) DISPLAY DEVICE

(71) Applicant: LG Display Co., Ltd., Seoul (KR)

(72) Inventors: Hye-Jin KIM, Paju-si (KR); Woo-Seok NOH, Paju-si (KR); Young-June GO, Paju-si (KR); Sung-Ho LEE, Paju-si (KR); Hui-Seong YU, Paju-si (KR)

(21) Appl. No.: 18/903,914

(22) Filed: Oct. 1, 2024

(30) Foreign Application Priority Data
Feb. 27, 2024 (KR) 10-2024-0027728

(51) Int. Cl. H10K 59/80; H10K 59/122

(52) U.S. Cl. CPC H10K 59/873; H10K 59/122

(57) ABSTRACT

A display device includes: a substrate having a display area having a plurality of subpixels and a non-display area adjacent to the display area; a bank layer on the substrate to define the plurality of subpixels; a transistor and a light emitting diode in each of the plurality of subpixels; a stopper in the non-display area; and an encapsulating layer on the light emitting diode and surrounded by the stopper, wherein the encapsulating layer includes an epoxy resin, and wherein the stopper includes a material curing the epoxy resin due to contact of the epoxy resin and the stopper.

### CROSS-REFERENCE TO RELATED APPLICATIONS

The present application claims the priority benefit of Republic of Korea Patent Application No. 10-2024-0027728 filed in Republic of Korea on Feb. 27, 2024, which is hereby incorporated by reference herein in its entirety.

### BACKGROUND

### Technical Field

The present disclosure relates to a display device, and more particularly, to a display device where a bezel is reduced.

### Description of the Related Art

Recently, as a multimedia is progressed, an importance of a display device increases. As a result, a flat panel display such as a liquid crystal display (LCD), a plasma display panel (PDP) and an organic light emitting diode (OLED) display has been commercialized.

As the display device is applied to a small-sized portable electronic device such as a smartphone and a tablet computer, a bezel of the display device is minimized or removed to obtain a relatively large-sized display area even in a relatively small-sized display device and an elegant appearance.

### BRIEF SUMMARY

Accordingly, the present disclosure is directed to a display device that substantially obviates one or more of the problems due to limitations and disadvantages of the related art.

An object of the present disclosure is to provide a display device where a bezel is reduced.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display device includes: a substrate having a display area having a plurality of subpixels and a non-display area adjacent to the display area; a bank layer on the substrate to define the plurality of subpixels; a transistor and a light emitting diode in each of the plurality of subpixels; a stopper in the non-display area; and an encapsulating layer on the light emitting diode and surrounded by the stopper, wherein the encapsulating layer includes an epoxy resin, and wherein the stopper includes a material curing the epoxy resin due to contact of the epoxy resin and the stopper.

It is to be understood that both the foregoing general description and the following detailed description are explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a view showing a display device according to a first embodiment of the present disclosure;

FIG. 2 is a view showing a subpixel of a display device according to a first embodiment of the present disclosure;

FIG. 3 is a circuit diagram showing a subpixel of a display device according to a first embodiment of the present disclosure;

FIG. 4 is a plan view showing a display device according to a first embodiment of the present disclosure;

FIG. 5 is a cross-sectional view taken along a line V-V of FIG. 4;

FIG. 6 is a cross-sectional view showing a stopper of a display device according to a second embodiment of the present disclosure; and

FIGS. 7A to 7F are cross-sectional views showing a method of fabricating a display device according to a first embodiment of the present disclosure.

### DETAILED DESCRIPTION

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the present disclosure is only defined by scopes of claims.

The shapes, sizes, ratios, angles, numbers, and the like, which are illustrated in the drawings to describe various example embodiments of the present disclosure, are merely given by way of example. Therefore, the present disclosure is not limited to the illustrations in the drawings. Like reference numerals refer to like elements throughout the specification, unless otherwise specified.

In the following description, where the detailed description of the relevant known function or configuration may unnecessarily obscure a feature or aspect of the present disclosure, a detailed description of such known function or configuration may be omitted or a brief description may be provided.

Where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is to be construed as including an error or a tolerance range even where no explicit description of such an error or tolerance range is provided.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween.

Although the terms “first,” “second,” A, B, (a), (b), and the like may be used herein to refer to various elements, these elements should not be interpreted to be limited by these terms as they are not used to define a particular order or precedence. These terms are only used to distinguish one element from another. For example, a first element could be termed a second element, and, similarly, a second element could be termed a first element, without departing from the scope of the present disclosure.

The term “at least one” should be understood to include all combinations of one or more of related elements. For example, the term of “at least one of first, second and third elements” may include all combinations of two or more of the first, second and third elements as well as the first, second or third element.

The term “display device” may include a display device in a narrow sense such as liquid crystal module (LCM), an organic light emitting diode (OLED) module and a quantum dot (QD) module including a display panel and a driving unit for driving the display panel. In addition, the term “display device” may include a complete product (or a final product) including the LCM, the OLED module and the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of the present disclosure may include an applied product or a set device of a final user's device including the LCM, the OLED module and the QD module as well as a display device in a narrow sense such as the LCM, the OLED module and the QD module.

According to circumstances, the LCM, the OLED module and the QD module having a display panel and a driving unit may be expressed as “a display device”, and an electronic apparatus of a complete product including the LCM, the OLED module and the QD module may be expressed as “a set device.” For example, a display device in a narrow sense may include a display panel of a liquid crystal, an organic light emitting diode and a quantum dot and a source printed circuit board (PCB) of a control unit for driving the display panel, and a set device may further include a set PCB of a set control unit electrically connected to the source PCB for controlling the entire set device.

The display panel of the present disclosure may include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, when the display panel is an organic light emitting diode display panel, the display panel may include a plurality of gate lines, a plurality of data lines and a subpixel in a crossing region of the plurality of gate lines and the plurality of data lines. The display panel may include an array having a thin film transistor of an element for selectively applying a voltage to each subpixel, an emitting element layer on the array and an encapsulating substrate or an encapsulation part covering the emitting element layer. The encapsulation part may protect the thin film transistor and the emitting element layer from an external impact and may prevent or at least reduce penetration of a moisture or an oxygen into the emitting element layer. In addition, a layer on the array may include an inorganic light emitting layer, for example, a nano-sized material layer or a quantum dot.

The thin film transistor of the present disclosure may include one of an oxide thin film transistor, an amorphous silicon thin film transistor, a low temperature polycrystalline silicon thin film transistor.

Features of various embodiments of the present disclosure may be partially or entirely coupled to or combined with each other. They may be linked and operated technically in various ways as those skilled in the art can sufficiently understand. The embodiments may be carried out independently of or in association with each other in various combinations.

Hereinafter, a display device according to various example embodiments of the present disclosure where an influence on an oxide semiconductor layer of a thin film transistor of a driving element part is reduced by shielding a light emitted and transmitted from a subpixel and/or a light inputted from an exterior will be described in detail with reference to the accompanying drawings.

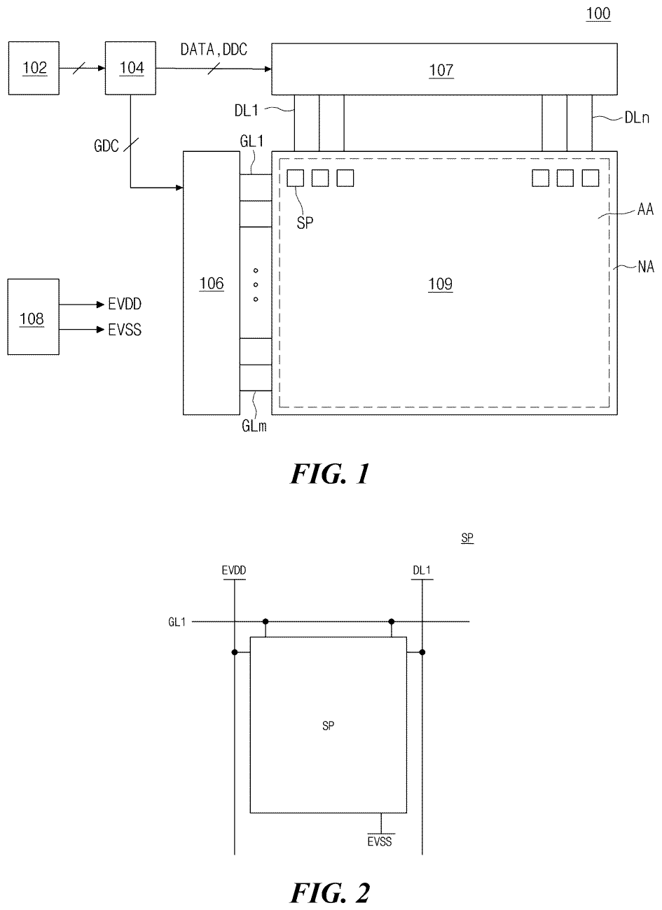

FIG. 1 is a view showing a display device according to a first embodiment of the present disclosure, and FIG. 2 is a view showing a subpixel of a display device according to a first embodiment of the present disclosure.

In FIG. 1, a display device 100 according to a first embodiment of the present disclosure includes an image processing unit 102, a timing controlling unit 104, a gate driving unit 106, a data driving unit 107, a power supplying unit 108 and a display panel 109.

The image processing unit 102 outputs a plurality of timing signals for various units as well as an image signal supplied from an exterior. For example, the plurality of timing signals may include a data enable signal, a vertical synchronization signal, a horizontal synchronization signal and a clock signal.

The timing controlling unit 104 receives the image signal and the plurality of timing signals from the image processing unit 102. The timing controlling unit 104 generates an image data DATA, a gate control signal GDC and a data control signal DDC using the image signal and the plurality of timing signals. The timing controlling unit 104 transmits the gate control signal GDC to the gate driving unit 106 and transmits the image data and the data control signal DDC to the data driving unit 107.

The gate driving unit 106 generates a gate signal (a gate voltage, a scan signal) using the gate control signal GDC transmitted from the timing controlling unit 104 and applies the gate signal to a plurality of gate lines GL1 to GLm of the display panel 109. Although the gate driving unit 106 may be formed as an integrated circuit (IC), it is not limited thereto.

The gate driving unit 106 may have a gate-in-panel (GIP) type where the gate driving unit 106 is disposed on a substrate of the display panel 109.

The data driving unit 107 generates a data signal (a data voltage) using the data control signal DDC and the image data DATA transmitted from the timing controlling unit 104 and applies the data signal to a plurality of data lines DL1 to DLn of the display panel 109. The data driving unit 107 samples and latches the image data DATA of a digital type to output the data signal of an analog type based on a gamma reference voltage. Although the data driving unit 107 may be formed as an integrated circuit (IC), it is not limited thereto.

The power supplying unit 108 outputs a high level voltage Vdd and a low level voltage Vss. The power supplying unit 108 supplies the high level voltage Vdd to the display panel 109 through a first power line EVDD and supplies the low level voltage Vss to the display panel 109 through a second power line EVSS. In addition, the high level voltage Vdd and the low level voltage Vss of the power supplying part 108 may be supplied to the gate driving unit 106 or the data driving unit 107 for driving.

The display panel 109 displays an image using the gate signal of the gate driving unit 106, the data signal of the data driving unit 107 and the high level voltage Vdd and the low level voltage Vss of the power supplying unit 108.

The display panel 109 includes a plurality of subpixels SP, a plurality of gate lines GL1 to GLm and a plurality of data lines DL1 to DLn. The plurality of subpixels SP may include red, green and blue subpixels SP or white, red, green and blue subpixels SP. The white, red, green and blue subpixels SP may have the same area as each other or may have a different area from each other.

In FIG. 2, a single subpixel SP may be connected to the gate line GL1, the data line DL1, the first power line EVDD and the second power line EVSS. A driving method as well as a number of a transistor and a capacitor of the subpixel SP may be determined according to a structure of a subpixel circuit. For example, the subpixel SP may have a structure of 2T1C including two transistors and one capacitor. In another embodiment, the subpixel SP may have a structure of one of 3T1C, 4T1C, 5T1C, 6TIC, 7TIC, 3T2C, 4T2C, 5T2C, 6T2C, 7T2C and 8T2C.

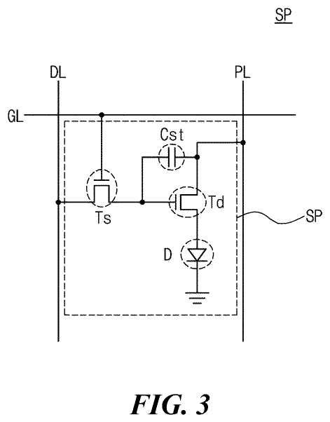

FIG. 3 is a circuit diagram showing a subpixel of a display device according to a first embodiment of the present disclosure.

In FIG. 3, the display device 100 includes the gate line GL, the data line DL and the power line PL crossing each other to define the subpixel SP. A switching transistor Ts, a driving transistor Td, a storage capacitor Cst and a light emitting diode D are disposed in the subpixel SP.

The switching transistor Ts is connected to the gate line GL and the data line DL. The driving transistor Td and the storage capacitor Cst are connected between the switching transistor Ts and the power line PL. The light emitting diode D is connected to the driving transistor Td.

When the switching transistor Ts is turned on according to the gate signal of the gate line GL, the data signal of the data line DL is applied to a gate electrode of the driving transistor Td and one capacitor electrode of the storage capacitor Cst through the switching transistor Ts.

Since the driving transistor Td is turned on according to the data signal, a current proportional to the data signal flows from the power line PL to the light emitting diode D through the driving transistor Td and the light emitting diode D emits a light of a luminance proportional to the current flowing through the driving transistor Td.

The storage capacitor Cst is charged up with a voltage proportional to the data signal to keep a voltage of the gate electrode of the driving transistor Td constant for one frame.

Although the subpixel SP includes two transistors Td and Td and one capacitor Cst in an embodiment of FIG. 3, the subpixel SP may include three or more transistors and two or more capacitors in another embodiment.

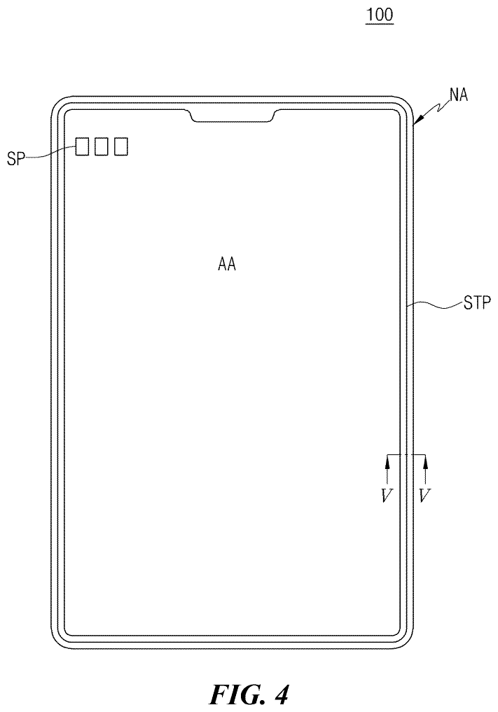

FIG. 4 is a plan view showing a display device according to a first embodiment of the present disclosure.

In FIG. 4, the display device 100 according to a first embodiment of the present disclosure includes a display area AA where an image is displayed and a non-display area NA surrounding and adjacent to the display area AA.

The display area AA includes the plurality of subpixels SP. The plurality of subpixels SP may include a red subpixel, a green subpixel and a blue subpixel. The plurality of subpixels SP may further include a white subpixel.

The plurality of gate lines and the plurality of data lines crossing each other are disposed in the display area AA, and each subpixel SP is connected to the gate line and the data line. A thin film transistor of a switching element and a display element displaying an image are disposed in each subpixel SP.

The display element may include various devices. For example, the display element may be an organic light emitting diode, a liquid crystal, a quantum dot, a micro light emitting diode (LED) or a mini LED.

The gate driving unit and the data driving unit supplying various signals to the plurality of subpixels SP are disposed in the non-display area NA. The gate driving unit supplies a gate signal to the plurality of subpixels SP through the gate line, and the data driving unit supplies a data signal to the plurality of subpixels SP through the data line.

A stopper STP surrounding the display area AA is disposed in the non-display area NA. When the thin film transistor or the organic light emitting diode is exposed to an external impurity such as a moisture, a hydrogen and an oxygen, the thin film transistor or the organic light emitting diode may be deteriorated to cause deterioration of the display device 100. As a result, the display device 100 includes an encapsulating layer (not shown) to encapsulate the display device 100 from an external environment. When an encapsulating material is coated in a step of forming the encapsulating layer, the stopper STP in the non-display area NA blocks a flow of the encapsulating material to prevent the encapsulating material from overflowing outside the display device 100.

In a display device according to a comparison example, to prevent the encapsulating material from overflowing outside the display device perfectly, a plurality of dams are disposed to surround the display area AA.

When the encapsulating layer does not have a uniform thickness throughout the entire display device according to the comparison example, an image may be deteriorated due to a light refraction in the encapsulating layer. Since the coated encapsulating material is spread out in the entire display device according to the comparison example with a non-uniform spread speed, the encapsulating layer is formed with a non-uniform thickness. When the encapsulating material is spread out toward various directions, the encapsulating material has different spread speeds according to the directions. As a result, the encapsulating material may be coated in a region with a relatively small amount and the encapsulating material may not be coated in another region. Since the region having the encapsulating layer of a relatively small thickness or having no encapsulating layer has a stain due to a light refraction, a display quality of the display device according to the comparison example may be deteriorated.

To form the encapsulating layer of a thickness greater than a predetermined value, the encapsulating material of an amount greater than a predetermined value is coated based on the spread speed and the plurality of dams are formed to prevent the encapsulating material from overflowing outside the display device according to the comparison example. However, since the plurality of dams are disposed in the non-display area NA, a bezel of the display device according to the comparison example increases.

In the display device 100 according to a first embodiment of the present disclosure, since the encapsulating material is prevented from overflowing outside the display device 100 due to the single stopper STP instead of the plurality of dams, a size and an area of the bezel are reduced or minimized.

The stopper STP includes a curing material that cures (hardens) the encapsulating material when the curing material contacts the encapsulating material. As a result, when the encapsulating material is spread out to contact the stopper STP, the encapsulating material is cured not to overflow over the stopper STP outside the display device 100. Since the encapsulating material is confined in a predetermined region by the stopper STP of a simple structure, the bezel is reduced or minimized.

Although the stopper STP is formed in the non-display area NA along a boundary of the display area AA with a uniform width in a first embodiment of FIG. 4, the stopper STP may be formed with different widths according to a position in another embodiment.

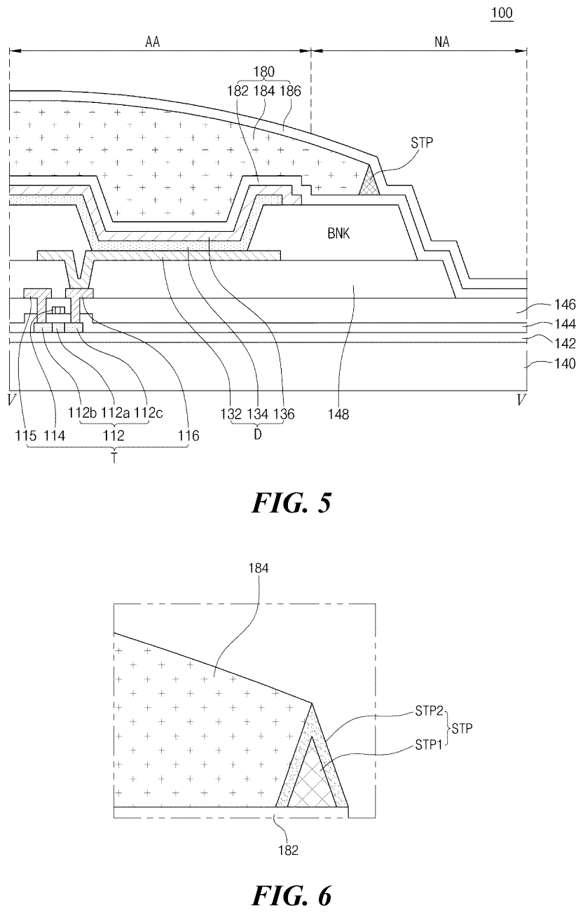

FIG. 5 is a cross-sectional view taken along a line V-V of FIG. 4. Although a plurality of thin film transistors and a plurality of conductive lines are disposed in the display area AA and the non-display area NA, a thin film transistor and a light emitting diode in the display area AA are shown for illustration's convenience.

In FIG. 5, a substrate 140 has the display area AA and the non-display area NA. The substrate 140 may include a hard material such as a glass or a soft material such as a plastic material.

When the substrate 140 includes a plastic material, the substrate 140 may include at least one of polyimide (PI), polymethylmethacrylate (PMMA), polyethylene terephthalate (PET), polyether sulfone (PES) and polycarbonate (PC), and it is not limited thereto.

For example, when the substrate 140 includes polyimide, the substrate 140 may include a plurality of polyimide layers. Further, an inorganic layer may be disposed between the polyimide layers, and it is not limited thereto.

A buffer layer 142 is disposed on the substrate 140. The buffer layer 142 may be disposed on the entire substrate 140 to increase an adhesive strength between layers and the substrate 140 and to block an alkali ingredient released from the substrate 140. Further, the buffer layer 142 may delay diffusion of a moisture or an oxygen permeating the substrate 140.

The buffer layer 142 may have a single layer or a multiple layer of an inorganic insulating material such as silicon nitride (SiNx) and silicon oxide (SiOx). When the buffer layer 142 has a multiple layer, a layer of silicon nitride (SiNx) and a layer of and silicon oxide (SiOx) may be alternated with each other. The buffer layer 142 may be omitted based on a kind and a material of the substrate 140 and a structure and a type of the thin film transistor.

A thin film transistor T is disposed on the buffer layer 142 in the display area AA. Although a driving thin film transistor among a plurality of thin film transistors in the display area AA is shown in FIG. 5, the other thin film transistors such as a switching thin film transistor may be disposed in the display area AA. Further, although the thin film transistor T has a top gate structure in FIG. 5, the thin film transistor T may have the other structure such as a bottom gate structure.

The thin film transistor T includes a semiconductor layer 112 on the buffer layer 142, a gate insulating layer 144 on the semiconductor layer 112, a gate electrode 114 on the gate insulating layer 144, an interlayer insulating layer 146 on the gate electrode 114 and source and drain electrodes 115 and 116 on the interlayer insulating layer 146.

The semiconductor layer 112 may include a polycrystalline semiconductor material. For example, the polycrystalline semiconductor material may include polycrystalline silicon having a relatively high mobility, and it is not limited thereto.

The semiconductor layer 112 may include an oxide semiconductor material. For example, the oxide semiconductor material may include one of indium gallium zinc oxide (IGZO), indium zinc oxide (IZO), indium gallium tin oxide (IGTO) and indium gallium oxide (IGO), and it is not limited thereto. The semiconductor layer 112 has a channel region 112a of an intrinsic material at a central portion thereof and source and drain regions 112b and 112c of a doped material at both sides of the channel region 112a.

The gate insulating layer 144 may be disposed in both of the display area AA and the non-display area NA or only in the display area AA. The gate insulating layer 144 may have a single layer or a multiple layer of an inorganic insulating material such as silicon nitride (SiNx) and silicon oxide (SiOx), and it is not limited thereto.

The interlayer insulating layer 146 may be disposed in both of the display area AA and the non-display area NA or only in the display area AA. The interlayer insulating layer 146 may have a single layer or a multiple layer of an organic insulating material such as photoacryl or an inorganic insulating material such as silicon nitride (SiNx) and silicon oxide (SiOx). Further, the interlayer insulating layer 146 may have a multiple layer of an organic layer and an inorganic layer, and it is not limited thereto.

The source and drain electrodes 115 and 116 may have a single layer or a multiple layer of one of molybdenum (Mo), aluminum (Al), chromium (Cr), gold (Au), titanium (Ti), nickel (Ni), neodymium (Nd), copper (Cu) and an alloy thereof, and it is not limited thereto. The source and drain electrodes 115 and 116 may be connected to the source and drain regions 112b and 112c, respectively, of the semiconductor layer 112 through contact holes in the gate insulating layer 144 and the interlayer insulating layer 146.

Although not shown, a bottom shielding metal layer may be disposed on the substrate 140 under the semiconductor layer 112. The bottom shielding metal layer may minimize a back channel phenomenon generated due to charges trapped in the substrate 140 to prevent a residual image or deterioration of a transistor. The bottom shielding metal layer may have a single layer or a multiple layer of one of titanium (Ti), molybdenum (Mo) and an alloy thereof, and it is not limited thereto.

A planarizing layer 148 is disposed on the thin film transistor T over the substrate 140. The planarizing layer 148 may include an organic insulating material such as photoacryl, and it is not limited thereto. The planarizing layer 148 may have a multiple layer of an inorganic layer and an organic layer.

A light emitting diode D is disposed on the planarizing layer 148 in the display area AA. The light emitting diode D includes a first electrode 132, an emitting layer 134 and a second electrode 136.

The first electrode 132 is disposed on the planarizing layer 148 and is electrically connected to the drain electrode 116 of the thin film transistor T through a contact hole in the planarizing layer 148. The first electrode 132 may include at least one of silver (Ag), aluminum (Al), gold (Au), molybdenum (Mo), tungsten (W), chromium (Cr) and an alloy thereof. Alternatively, the first electrode 132 may include a transparent conductive material such as indium tin oxide (ITO) and indium zinc oxide (IZO).

When the display device 100 has a top emission type, the first electrode 132 may further include an opaque conductive material for using the first electrode 132 as a reflective layer. When the display device 100 has a bottom emission type, the first electrode 132 may include a transparent conductive material such as indium tin oxide (ITO) and indium zinc oxide (IZO).

A bank layer BNK is disposed in a boundary region of each subpixel. The bank layer BNK may be a kind of wall defining the subpixel. The bank layer BNK may prevent a mixture of lights of various colors emitted from adjacent subpixels SP.

The bank layer BNK may include at least one of an inorganic insulating material such as silicon nitride (SiNx) and silicon oxide (SiOx), an organic insulating material such as benzocyclobutene (BCB), acrylic resin, epoxy resin, phenolic resin, polyamide resin and polyimide resin and a photosensitive material including a black pigment, and it is not limited thereto.

The emitting layer 134 may be disposed on a top surface of the first electrode 132, a side surface of the bank layer BNK and a top surface of the bank layer BNK in the display area AA to extend toward the non-display area NA.

The emitting layer 134 may include a red emitting layer emitting a red colored light in a red subpixel SP, a green emitting layer emitting a green colored light in a green subpixel SP and a blue emitting layer emitting a blue colored light in a blue subpixel SP. For example, the emitting layer 134 include an organic emitting layer, an inorganic emitting layer, a nano-sized material layer, a quantum dot layer, an emitting layer of a micro light emitting diode (LED) and an emitting layer of a mini LED, and it is not limited thereto.

The emitting layer 134 may include an emitting material layer, an electron injecting layer injecting an electron, a hole injecting layer injecting a hole, an electron transporting layer transporting an electron, a hole blocking layer blocking a hole, an electron blocking layer blocking an electron and a hole transporting layer transporting a hole, and it is not limited thereto.

The second electrode 136 is disposed on the emitting layer 134. The second electrode 136 may have a single layer or a multiple layer of a metallic material or an alloy of metallic materials. Alternatively, the second electrode 136 may include a transparent conductive material such as indium tin oxide (ITO) and indium zinc oxide (IZO), and it is not limited thereto.

When the display device 100 has a top emission type, the second electrode 136 may include a half transmissive conductive material transmitting a light. For example, the second electrode 136 may include at least one of alloys of LiF/Al, CsF/Al, Mg:Ag, Ca/Ag, Ca:Ag, LiF/Mg:Ag, LiF/Ca/Ag and LiF/Ca:Ag.

When the display device 100 has a bottom emission type, the second electrode 136 may include an opaque conductive material for using the second electrode 136 as a reflective layer. For example, the second electrode 136 may include at least one of silver (Ag), aluminum (Al), gold (Au), molybdenum (Mo), tungsten (W), chromium (Cr) and an alloy thereof.

The light emitting diode D may have a tandem structure. The tandem structure may include a plurality of emitting layers and a charge generating layer between the plurality of emitting layers. The charge generating layer for adjusting a charge balance of the plurality of organic layers may have a multiple layer including first and second charge generating layers. The charge generating layer may include a negative (N) type charge generating layer and a positive (P) type charge generating layer. For example, the charge generating layer may include an emitting layer doped with an alkali metal such as lithium (Li), sodium (Na), potassium (K) and cesium (Cs) or an alkali earth metal such as magnesium (Mg), strontium (Sr), barium (Ba) and radium (Ra), and it is not limited thereto.

An encapsulating layer 180 is disposed on the light emitting diode D in the display area AA and the non-display area NA to encapsulate the light emitting diode D. When the light emitting diode D is exposed to a moisture or an oxygen, a pixel shrinkage phenomenon where an emission area is reduced or deterioration of a dark spot in the emission area may occur. Further, a moisture or an oxygen may oxidize the electrode of a metallic material. The encapsulating layer 180 blocks permeation of a moisture or an oxygen from an exterior to prevent deterioration of the light emitting diode D and the electrodes.

Although the encapsulating layer 180 has a triple layer of first, second and third encapsulating layers 182, 184 and 186 in a first embodiment, the encapsulating layer 180 may have a double layer or a quadruple layer in another embodiment.

The first and third encapsulating layer 182 and 186 may have a single layer or a multiple layer of an inorganic material such as silicon oxide (SiOx), silicon oxynitride (SiON) and silicon nitride (SiNx). The first and third encapsulating layer 182 and 186 may further include an organic material between the inorganic materials, and it is not limited thereto. The second encapsulating layer 184 may include epoxy resin.

Although not shown, the display device 100 may include a touch unit. The touch unit may be disposed in the display area to sense a touch input. For example, the touch unit may sense an external touch information using a finger of a user or a touch pen.

The stopper STP is disposed in the non-display area NA. The stopper STP is disposed on the first encapsulating layer 182 over the bank layer BNK. The planarizing layer 148 and the bank layer BNK are disposed on the interlayer insulating layer 146 in a portion of the non-display area NA adjacent to the display area AA, and the planarizing layer 148 and the bank layer BNK are removed in the other portion of the non-display area NA. The stopper STP is disposed over the bank layer BNK in the non-display area NA adjacent to the display area AA.

Since an encapsulating material for the second encapsulating layer 184 has a fluidity, the encapsulating material may pass through a perimeter of the non-display area NA due to the fluidity to overflow outside the substrate 140 while the second encapsulating layer 184 is formed. The stopper STP is formed to surround the display area AA to confine the encapsulating material overflowing outside the substrate 140 while the second encapsulating layer 184 is formed. As a result, the encapsulating material is prevented from overflowing outside the substrate 140 by the stopper STP.

The stopper STP may include a material causing a chemical curing with the encapsulating material (e.g., an epoxy resin) for the second encapsulating layer 184. That is, the stopper STP may be formed of an organic material including a curing agent. For example, the stopper STP may be formed of an organic material including silicon and a curing agent. Further, the curing agent may be a compound including an active hydrogen, and the compound including an active hydrogen may have one of an amine type, an amide type, an anhydride type, a mercapto type and a silane type. For example, the curing agent may include one of polyamine, polyacid, polyphenol and polymercaptan, β hydroxyamine, ester, mercaptan and β phenyl ether.

When the encapsulating material coated on the substrate 140 and spread out toward the non-display area NA contacts the stopper STP during a step of forming the second encapsulating layer 184, the encapsulating material of a contact area is cured. Since the encapsulating material includes an epoxy resin and the stopper STP includes the compound having the active hydrogen, a chemical reaction occurs in a contact region of the encapsulating material and the stopper STP.

When the encapsulating material contacts the curing agent of the stopper STP, an epoxy group of the organic material and the active hydrogen of the curing agent are combined. The epoxy group and the curing agent include one or more reaction portion per molecule, and a three dimensional network is formed through a multiple reaction between an epoxy molecule and the curing agent. As a result, the encapsulating material begins to be cured in the contact region of the encapsulating material and the stopper STP.

When the epoxy resin and the curing agent are mixed, a polymer structure having a three-dimensional network is formed due to a cross-link so that the epoxy resin is cured. In the display device 100, after the epoxy resin for the second encapsulating layer 184 of the epoxy resin is coated on the substrate 140, the epoxy resin is spread out throughout the entire substrate 140, and the epoxy resin reaching the non-display area NA is combined with the curing agent of the stopper STP in the contact region. As a result, the epoxy resin reaching a side surface of the stopper STP facing the display area AA is cured.

When the encapsulating material contacts the stopper STP, a curing begins to occur. Since a forefront portion of the encapsulating material spread out toward the non-display area NA begins to be cured, a flow of the encapsulating material is stopped by a cured encapsulating material.

The encapsulating material is cured through a chemical curing only in a region within a predetermined distance from the stopper STP. As a result, a portion of the encapsulating material is cured to block the flow of the encapsulating material, and the other portion of the encapsulating material is cured through a second curing different from the chemical curing to form the second encapsulating layer 184. For example, the second curing may be a light curing using an ultraviolet (UV) ray or a thermal curing.

The first encapsulating layer 182 extends from a portion corresponding to the stopper STP to an end portion of the substrate 140 in the non-display area NA. The third encapsulating layer 186 extends from a portion corresponding to the stopper STP to the end portion of the substrate 140 in the non-display area NA. As a result, the first and third encapsulating layers 182 and 186 directly contact each other from a portion to the end portion of the substrate 140 in the non-display area NA.

In the display device according to a comparison example, the plurality of dams of an organic material on the bank layer of an organic material prevent the encapsulating material for the encapsulating layer from overflowing outside the substrate. However, in the display device according to a comparison example, since the bank layer and the plurality of dams constitute an interface of the organic materials, there is a limit in a blocking of permeation of a moisture or an oxygen through the interface between the bank layer and the plurality of dams.

In the display device 100 according to a first embodiment of the present disclosure, since the stopper STP of an organic material is disposed on the first encapsulating layer 182 of an inorganic material, the first encapsulating layer 182 and the stopper STP constitute an interface of the inorganic material and the organic material. As a result, permeation of a moisture or an oxygen through the interface between the first encapsulating layer 182 and the stopper STP is completely blocked.

Further, since the first and third encapsulating layers 182 and the 186 are disposed in the end portion of the substrate 140, permeation of a moisture or an oxygen through a side surface of the substrate 140 is also completely blocked.

Although the stopper STP has a cross-sectional shape of a triangle in FIG. 5, it is not limited thereto. For example, the stopper STP may have a cross-sectional shape of various polygons such as a square or a rectangle in another embodiment.

FIG. 6 is a cross-sectional view showing a stopper of a display device according to a second embodiment of the present disclosure.

Although the entire stopper STP is formed of a single material such as the curing agent in FIG. 5, a stopper STP includes first and second stoppers STP1 and STP2 in FIG. 6.

The first stopper STP1 is disposed as a dummy stopper, and the second stopper STP2 is disposed on a surface of the first stopper STP1 with a predetermined thickness. The first stopper STP1 is formed on a first encapsulating layer 182 with a predetermined height to block and confine an encapsulating material for a second encapsulating layer 184. The second stopper STP2 is chemically combined with and cures the encapsulating material for the second encapsulating layer 184 to prevent the encapsulating material for the second encapsulating layer 184 from overflowing over the stopper STP.

The first stopper STP1 may include an inorganic material or an organic material. Alternatively, the first stopper STP1 may include a metallic material.

The second stopper STP2 may be formed of an organic material including a curing agent, and the curing agent may be a compound including an active hydrogen. The compound including an active hydrogen may have one of an amine type, an amide type, an anhydride type, a mercapto type and a silane type. For example, the curing agent may include one of polyamine, polyacid, polyphenol and polymercaptan, β hydroxyamine, ester, mercaptan and β phenyl ether.

In the display device according to first and second embodiments of the present disclosure, since the stopper STP of a material curing the encapsulating material for the second encapsulating layer in the contact region instead of the plurality of dams is formed on the first encapsulating layer, the flow of the encapsulating material for the second encapsulating layer is blocked. Since an area for the stopper STP is smaller than an area for the plurality of dams, an area of the non-display area NA and an area of the bezel of the display device are reduced or minimized.

A method of fabricating the display device 100 will be illustrated hereinafter.

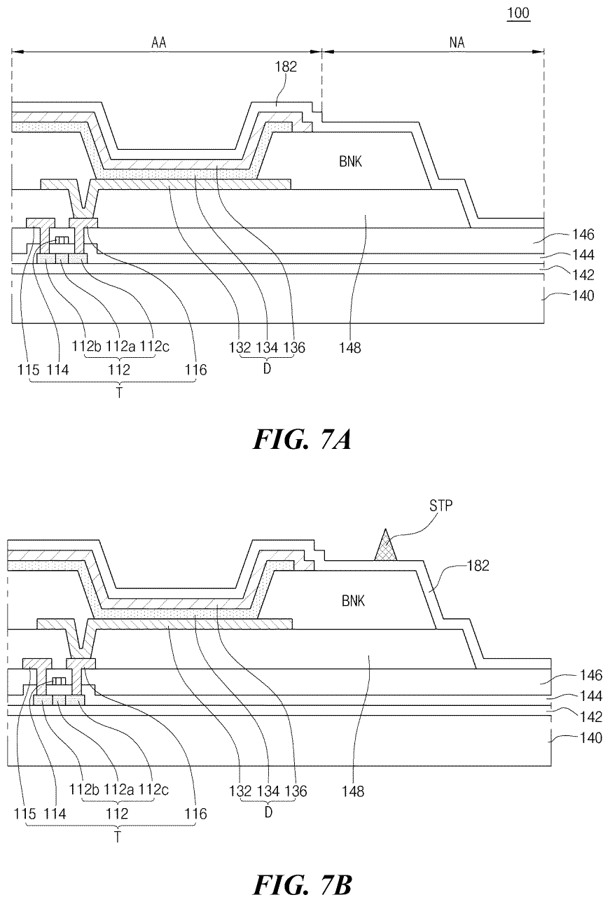

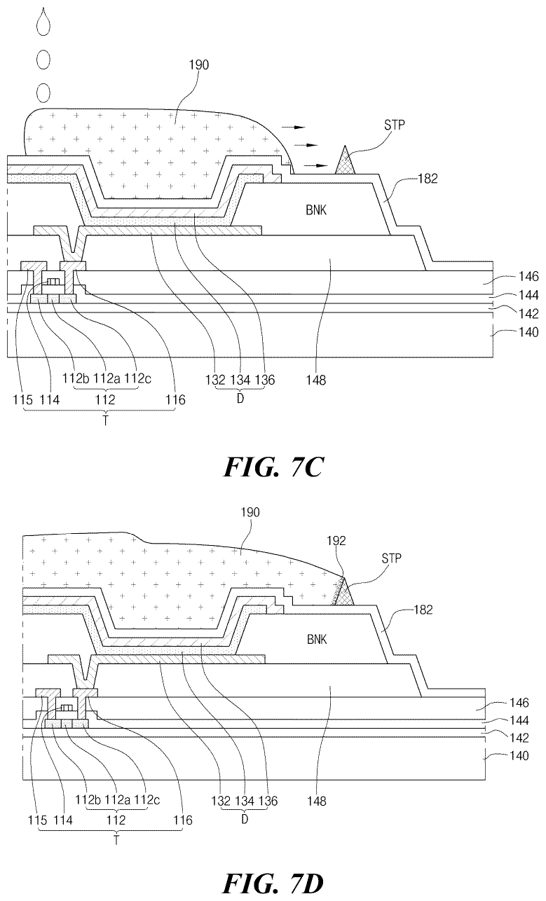

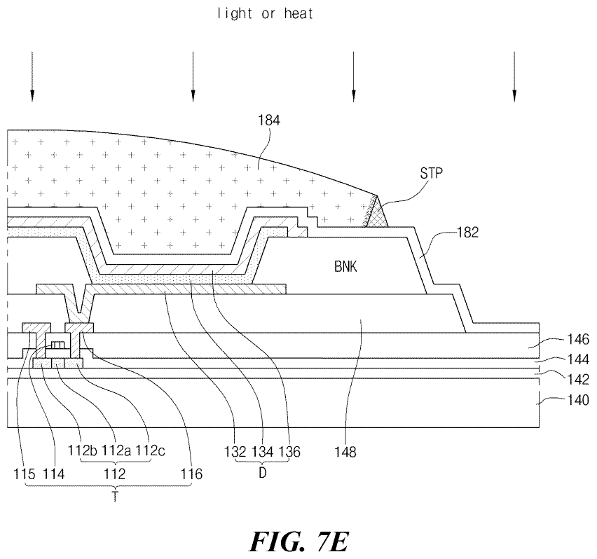

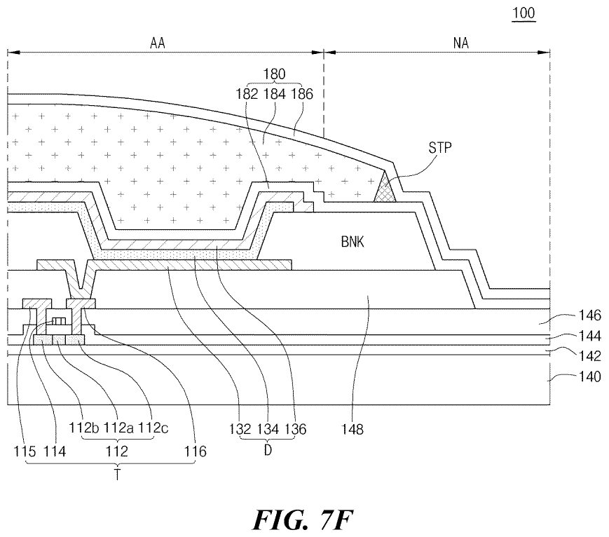

FIGS. 7A to 7F are cross-sectional views showing a method of fabricating a display device according to a first embodiment of the present disclosure.

In FIG. 7A, the buffer layer 142 is formed on the entire substrate 140 having the display area AA and the non-display area NA. The substrate 140 may include a hard material such as a glass or a plastic material such as polyimide (PI), polymethylmethacrylate (PMMA), polyethylene terephthalate (PET), polyether sulfone (PES) and polycarbonate (PC). The buffer layer 142 may have a single layer or a multiple layer of an inorganic insulating material such as silicon nitride (SiNx) and silicon oxide (SiOx).

Next, after a semiconductor material layer of a polycrystalline semiconductor material such as polycrystalline silicon or an oxide semiconductor material such as indium gallium zinc oxide (IGZO), indium zinc oxide (IZO), indium gallium tin oxide (IGTO) and indium gallium oxide (IGO) is formed on the buffer layer 142 in the display area AA, the semiconductor layer 112 is formed on the buffer layer 142 in each subpixel SP by patterning the semiconductor material layer. Next, the channel region 112a, the source region 112b and the drain region 112c are formed in the semiconductor layer 112 by doping side portions of the semiconductor layer 112 with an impurity.

Next, the gate insulating layer 144 of an inorganic insulating material such as silicon nitride (SiNx) and silicon oxide (SiOx) is formed on the semiconductor layer 112 over the entire substrate 140. Next, after a metallic material layer of a metallic material such as molybdenum (Mo), aluminum (Al), chromium (Cr), gold (Au), titanium (Ti), nickel (Ni), neodymium (Nd) and copper (Cu) is formed on the gate insulating layer 144, the gate electrode 114 is formed on the gate insulating layer 144 in each subpixel SP by patterning the metallic material layer. Next, after the interlayer insulating layer 146 of an organic insulating material such as photoacryl or an inorganic insulating material such as silicon nitride (SiNx) and silicon oxide (SiOx) is formed on the gate electrode 114 over the entire substrate 140, contact holes exposing the source and drain regions 112b and 112c are formed in the interlayer insulating layer 146 and the gate insulating layer 144 by patterning the interlayer insulating layer 146 and the gate insulating layer 144.

Next, after a metallic material layer of a metallic material such as molybdenum (Mo), aluminum (Al), chromium (Cr), gold (Au), titanium (Ti), nickel (Ni), neodymium (Nd) and copper (Cu) is formed on the interlayer insulating layer 146, the source and drain electrodes 115 and 116 contacting the source and drain regions 112b and 112c, respectively, of the semiconductor layer 112 through the contact holes are formed on the interlayer insulating layer 146 in each subpixel SP by patterning the metallic material layer. The semiconductor layer 112, the gate insulating layer 144, the gate electrode 114, the source electrode 115 and the drain electrode 116 constitute the thin film transistor T.

Next, after the planarizing layer 148 of an organic insulating material such as photoacryl is formed on the thin film transistor T over the entire substrate 140, a contact hole exposing the drain electrode 116 is formed in the planarizing layer 148 by patterning the planarizing layer 148.

Next, after a metallic material layer of a metallic material such as silver (Ag), aluminum (Al), gold (Au), molybdenum (Mo), tungsten (W) and chromium (Cr) or a transparent conductive material such as indium tin oxide (ITO) and indium zinc oxide (IZO) is formed on the planarizing layer 148, the first electrode 132 contacting the drain electrode 116 of the thin film transistor T through the contact hole is formed on the planarizing layer 148 by patterning the metallic material layer.

Next, after an insulating material layer of an inorganic insulating material such as silicon nitride (SiNx) and silicon oxide (SiOx), an organic insulating material such as benzocyclobutene (BCB), acrylic resin, epoxy resin, phenolic resin, polyamide resin and polyimide resin or a photosensitive material including a black pigment is formed on the planarizing layer 148 and the first electrode 132 over the entire substrate 140, the bank layer BNK is formed on the planarizing layer 148 and an edge portion of the first electrode 132 by patterning the insulating material layer. The bank layer BNK has an opening exposing a central portion of the first electrode 132.

Next, the emitting layer 134 is formed on the first electrode 132 in the display area AA by depositing and patterning an emitting material. Next, after a metallic material layer of a metallic material or a transparent conductive material is formed on the emitting layer 134, the second electrode 136 is formed on the emitting layer 134 and the side and top surfaces of the bank layer BNK by patterning the metallic material layer. The first electrode 132, the emitting layer 134 and the second electrode 136 constitute the light emitting diode D.

Next, the first encapsulating layer 182 is formed on the light emitting diode D over the entire substrate 140 by depositing an inorganic material.

In FIG. 7B, after an organic material layer including a curing agent is formed on the first encapsulating layer 182 over the entire substrate 140, the stopper STP is formed on the first encapsulating layer 182 over the bank layer BNK in the non-display area NA.

The curing agent may be a compound including an active hydrogen, and the compound including an active hydrogen may have one of an amine type, an amide type, an anhydride type, a mercapto type and a silane type. For example, the curing agent may include one of polyamine, polyacid, polyphenol and polymercaptan, β hydroxyamine, ester, mercaptan and β phenyl ether.

In the display device according to a second embodiment of the present disclosure, after an organic material layer or an inorganic material layer is formed on the first encapsulating layer 182 over the entire substrate 140, the first stopper STP1 is formed on the first encapsulating layer 182 over the bank layer BNK in the non-display area NA by patterning the organic material layer or the inorganic material layer. Next, after an organic material layer including a curing agent is formed on the first stopper STP1 over the entire substrate 140, the second stopper STP2 is formed on the first stopper STP2 over the bank layer BNK in the non-display area NA. The first and second stopper STP1 and STP2 constitute the stopper STP.

The curing agent may be a compound including an active hydrogen, and the compound including an active hydrogen may have one of an amine type, an amide type, an anhydride type, a mercapto type and a silane type. For example, the curing agent may include one of polyamine, polyacid, polyphenol and polymercaptan, β hydroxyamine, ester, mercaptan and β phenyl ether.

In FIG. 7C, an encapsulating material 190 such as an epoxy resin is dropped on the first encapsulating layer 182 in a predetermined region (e.g., a dropping region). For example, the dropping region may be a central region of the display area AA. The dropped encapsulating material 190 may be spread out or flow from the display area AA to the non-display area NA.

In FIG. 7D, when the encapsulating material 190 spread out from the display area AA to the non-display area NA reaches and contacts the stopper STP in the non-display area NA, the encapsulating material 190 begins to be cured due to a chemical combination between the encapsulating material 190 and the stopper STP. As a result, a cured layer 192 is formed in a contact region of the encapsulating material 190 and the stopper STP at a forefront portion of the encapsulating material 190 spread out toward the non-display area NA.

Since a flow of the encapsulating material 190 is blocked due to the cured layer 192, the encapsulating material 190 does not overflow over the stopper STP to be confined in a predetermined region surrounded by the stopper STP.

In FIG. 7E, the encapsulating material 190 is completely cured by irradiating a light such as an ultraviolet ray onto or applying a heat to the encapsulating material 190 spread out to form the second encapsulating layer 184.

The portion of the encapsulating material 190 in the contact region of the second encapsulating layer 184 and the stopper STP is cured through a chemical curing and the other portion of the encapsulating material 190 is cured through a light curing or a thermal curing. As a result, the second encapsulating layer 184 may include a first portion cured through a chemical curing in an interface between the second encapsulating layer 184 and the stopper STP and a second portion cured through a light curing or a thermal curing.

In FIG. 7F, the third encapsulating layer 186 of an inorganic material is formed on the second encapsulating layer 184, and the display device 100 is completed.

In the display device 100 according to a first embodiment of the present disclosure, the curing of the second encapsulating layer 184 includes first and second steps. In the first step, the flow of the encapsulating material 190 is stopped by curing the forefront portion of the encapsulating material 190 using the stopper STP. In the second step, the stopped encapsulating material 190 is completely cured.

Consequently, in the display device according to first and second embodiments of the present disclosure, since the encapsulating material 190 for the second encapsulating layer 184 is prevented from overflowing outside the display device 100 due to the single stopper STP in the non-display area NA, a size and an area of the bezel are reduced or minimized.

Further, since the flow of the encapsulating material 190 is blocked by the stopper STP, the excessive usage of the encapsulating material 190 is prevented and the disuse of the encapsulating material is minimized. As a result, the discharge of toxic waste is minimized to obtain the environment friendly process.

It will be apparent to those skilled in the art that various modifications and variation can be made in the present disclosure without departing from the spirit or scope of the disclosure. Thus, it is intended that the present disclosure cover the modifications and variations of this disclosure.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate having a display area and a non-display area adjacent to the display area, the display area having a plurality of subpixels;
a bank layer on the substrate to define the plurality of subpixels;
a transistor and a light emitting diode in each of the plurality of subpixels;
a stopper in the non-display area; and
an encapsulating layer on the light emitting diode and surrounded by the stopper,
wherein the encapsulating layer includes an epoxy resin, and
wherein the stopper includes a material configured to cure the epoxy resin in response to contact of the epoxy resin and the stopper.

2. The display device of claim 1, wherein the stopper is disposed on the bank layer in the non-display area.

3. The display device of claim 1, wherein the encapsulating layer comprises:
a first encapsulating layer disposed on the bank layer and including an inorganic material;
a second encapsulating layer including the epoxy resin on the first encapsulating layer; and
a third encapsulating layer disposed on the second encapsulating layer and including an inorganic material.

4. The display device of claim 3, wherein the stopper is disposed on the first encapsulating layer in the non-display area.

5. The display device of claim 3, wherein the second encapsulating layer comprises:
a first portion contacting a surface of the stopper; and
a second portion excluding the first portion.

6. The display device of claim 5, wherein the first portion of the second encapsulating layer is configured to be cured through chemical curing.

7. The display device of claim 5, wherein the second portion is configured to be cured through one of light curing and thermal curing.

8. The display device of claim 1, wherein the stopper includes an organic material including a curing agent.

9. The display device of claim 8, wherein the curing agent includes a compound including an active hydrogen.

10. The display device of claim 9, wherein the compound including the active hydrogen has one of an amine type, an amide type, an anhydride type, a mercapto type and a silane type.

11. The display device of claim 8, wherein the curing agent includes one of polyamine, polyacid, polyphenol and polymercaptan, β hydroxyamine, ester, mercaptan and β phenyl ether.

12. A display device, comprising:
a substrate having a display area and a non-display area adjacent to the display area, the display area having a plurality of subpixels;
a bank layer on the substrate to define the plurality of subpixels;
a transistor and a light emitting diode in each of the plurality of subpixels;
a stopper in the non-display area including a first stopper being a dummy stopper on the bank layer and a second stopper on a surface of the first stopper;
an encapsulating layer on the light emitting diode and surrounded by the stopper,
wherein the encapsulating layer includes an epoxy resin, and
wherein the stopper includes a material configured to cure the epoxy resin in response to contact of the epoxy resin and the stopper.

13. The display device of claim 12, wherein the first stopper includes one of an inorganic material and an organic material.

14. The display device of claim 12, wherein the second stopper includes the material configured to cure the epoxy resin in response to contact of the epoxy resin and the second stopper.

15. A display device, comprising:
a substrate having a display area and a non-display area;
a plurality of pixels in the display area;
a bank layer on the substrate;
a stopper in the non-display area; and
an encapsulation layer on the plurality of pixels,
wherein the stopper is a ridge surrounding the encapsulation layer to prevent overflow of the encapsulation layer during curing.

16. The display device of claim 15, wherein the ridge of the stopper is a material configured to cure an epoxy resin of the encapsulation layer to prevent overflow of the encapsulation layer.

17. The display device of claim 16, wherein the stopper includes a first stopper and a second stopper, and
wherein the first stopper is a dummy layer and the second stopper includes the material configured to cure the epoxy resin.

18. The display device of claim 15, wherein the encapsulation layer is a first encapsulation layer, the display device further comprising:
a second encapsulation layer disposed on the bank, wherein the stopper is disposed on the second encapsulation layer to prevent overflow of the first encapsulation layer.

19. The display device of claim 15, wherein the stopper includes an organic material including a curing agent.

20. The display device of claim 19, wherein the curing agent includes a compound including an active hydrogen.
